(19) United States
(12) Patent Application Publication
(10) Pub. No.: US 2014/0063891 A1
(43) Pub. Date: Mar. 6, 2014

(54) SEMICONDUCTOR MEMORY DEVICE

(71) Applicant: KABUSHIKI KAISHA TOSHIBA, Tokyo (JP)

(72) Inventor: Yoshiaki ASAO, Kanagawa (JP)

(73) Assignee: Kabushiki Kaisha Toshiba, Tokyo (JP)

(21) Appl. No.: 13/786,309

(22) Filed: Mar. 5, 2013

(30) Foreign Application Priority Data
Aug. 30, 2012 (JP) 2012-190177

(51) Int. Cl. G11C 11/16; H01L 43/12

(52) U.S. Cl. CPC G11C 11/161; H01L 43/12
USPC 365/66; 438/3

(57) ABSTRACT

According to one or more embodiments of the present invention, the semiconductor memory device of this disclosure includes the first bit line and the second bit line. Each of the multiple memory cells includes a memory element and a transistor, which are connected in series between the first and the second bit lines. Multiple memory cells are connected in parallel between the first and the second bit lines. In the first memory cell, its memory element is connected to the first bit line, and its transistor is connected to the second bit line. In the second memory cell, its memory element is connected to the second bit line, and its transistor is connected to the first bit line.

### CROSS-REFERENCE TO RELATED APPLICATION

This application is based upon and claims the benefit of priority from Japanese Patent Application No. 2012-190177, filed Aug. 30, 2012, the entire contents of which are incorporated herein by reference.

### FIELD

Embodiments described herein relate to a semiconductor memory device.

### BACKGROUND

One of the resistance-change-type memories is Magnetic Random Access Memory (MRAM). One of the write methods for MRAM is a spin-injection write method. The spin injection Magnetic Tunnel Junction (MTJ) element has a layered structure with two ferromagnetic layers and a nonmagnetic barrier layer (insulating thin film) inserted between them, and stores digital data by changing the magnetic resistance due to the spin-polarization tunnel effect. The data logic changes depending on whether the direction of the two ferromagnetic layers is in a parallel state (P state) or in an antiparallel state (AP state). The write operation is executed by the cell transistor applying a current to MTJ element.

This electric current driving capability of the cell transistor depends on the potential difference between the gate and source (also referred to as the gate-source voltage). Normally, when the parasitic resistance from the voltage source to the cell transistor changes, depending on the position of the memory cell, the voltage between the gate and the source also changes. Then, the current driving capability of the cell transistor changes. The dispersion in the current driving capability of the cell transistor causes inferior write operations. Therefore, there are cases in which inferior write operations easily occur, depending on the position of the memory cell. For example, the smaller the distance between the power source and the memory cell is, the longer the source line from the voltage source to ground is. As a result, sometimes the closer the memory cell is to the power source, the more likely it is to perform the inferior write operation.

### DESCRIPTION OF THE DRAWINGS

FIG. 1 is a block drawing, showing an example of the structure of the MARM of a first embodiment.

FIG. 2 is an explanatory drawing, showing the write operation of memory cell MC according to the first embodiment.

FIGS. 3A and 3B are equivalent circuit schematics, showing part of the MRAM during the write operation of the MRAM according to the first embodiment.

FIG. 4 is a plane layout chart of the MRAM according to the first embodiment.

FIG. 5 is a cross section of FIG. 4 along the 5-5 line.

FIG. 6 is a cross section of FIG. 4 along the 6-6 line.

FIG. 7 is a plane figure, showing active area AA and gate electrode GC.

FIG. 8 is a plane figure, showing intersection ISP of first bit line BL1 and second bit line BL2.

FIG. 9 is a cross section of FIG. 8 along the 9-9 line.

FIG. 10 is a cross section of FIG. 8 along the 10-10 line.

FIGS. 11A and 11B are equivalent circuit schematics, showing part of the MRAM during the write operation of the MRAM according to the second embodiment.

### DETAILED DESCRIPTION

The one or more embodiments of the present invention are directed to provide a semiconductor memory device that can suppress inferior write operations that depend on the arrangement of memory cells.

In general, the one or more embodiments of this disclosure will be explained with reference to the figures. However, the embodiments described herein are not to limit this disclosure.

The semiconductor memory device of the present invention includes the first bit line and the second bit line. Each of the multiple memory cells includes a memory element and a transistor, which are connected in series between the first and the second bit lines. The multiple memory cells are connected in parallel between the first and the second bit lines. In the first memory cell, the memory element is connected to the first bit line, and the transistor is connected to the second bit line. In the second cell, the memory element is connected to the second bit line, and the cell transistor is connected to the first bit line.

### First Embodiment

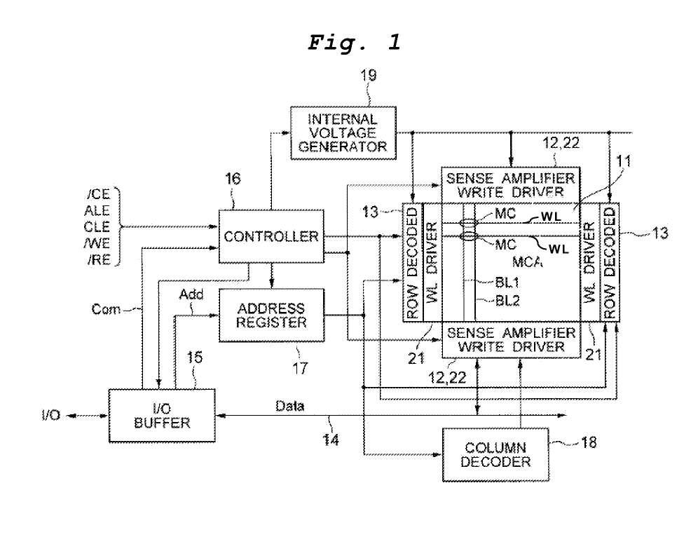

FIG. 1 is a block drawing, showing the structure of MRAM according to the first embodiment. In memory cell array 11, multiple memory cells MC are arranged two-dimensionally in the form of a matrix. Each memory cell MC includes an MTJ element and a cell transistor. The MTJ element is a magnetic tunnel junction device, which stores data using changes in the resistive state, and can rewrite data by the electric current. The cell transistor is disposed in correspondence with the MTJ element and is structured to be put in the conductive state when the current is applied to the corresponding MTJ element.

Multiple word lines WL and multiple bit lines BL are each wired to intersect with each other, with the word lines extending in a row direction and the bit lines extending in a column direction. The two adjacent bit lines BL are paired, and the memory cell MC is disposed in correspondence with the intersection of the word line WL and the pair of bit lines BL (for example, first bit line BL1 and second bit line BL2), such that the memory cell MC spans between adjacent bit lines at a location where a single where a word line WL crosses them. The MTJ element and the cell transistor of each memory cell MC is connected in series between the pair of bit lines (for example, between BL1 and BL2), and, a gate of cell transistor associated with the memory cell MC is connected to the word line WL.

At opposed sides of the memory cell array 11 in the bit line direction, sense amplifiers 12 and write drivers 22 are concurrently positioned. The sense amplifier 12 is connected to the bit line BL and reads data stored in the memory cell by detecting a current flowing in the memory cell MC, which is connected to a selected word line WL. Write driver 22 is connected to bit line BL and writes data by applying a current to the memory cell MC, which is connected to selected word line WL.

To either side of the memory cell array 11 in the word line direction, a row decoder 13 and a word line driver 21 are concurrently positioned. Word line driver 21 is connected to the word line and is structured to apply a voltage to a selected word line WL during a read or a write operation.

The reception of data between the sense amplifier 12 or the write driver 22 and external input/output terminal I/O is executed through data bus 14 and I/O buffer 15.

Various external control signals, such as a chip enable signal/CE, an address latch enable signal ALE, a command latch enable signal CLE, a write enable signal/WE, and a read enable signal/RE, are input into controller 16. Based on these signals, the controller 16 distinguishes address Add and command “Com,” which are supplied from the input/output terminal I/O. The controller 16 transfers address Add through address resistor 17 to row decoder 13 and column decoder 18. Also, the controller 16 decodes command “Com.” The sense amplifier 12 is configured to be able to apply a voltage to the bit line, following the column address, decoded by the column decoder 18. Word line driver 21 is configured to be able to apply a voltage to selected word line WL, following the row address, decoded by the row decoder 13.

The controller 16 executes each sequence control for the read, write, and erase operations, following the external control signals and commands. Internal voltage generation circuit 19 is disposed to generate internal voltages (for example, a voltage increased to be higher than that of the power source) needed for each operation. The internal voltage generation circuit 19 is also controlled by the controller 16 and executes the voltage increase operation to generate necessary voltages.

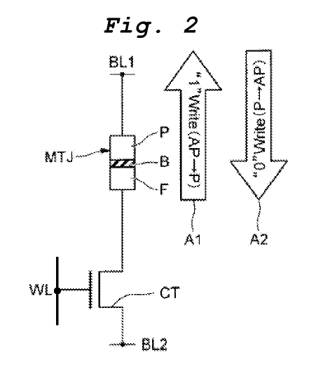

FIG. 2 is an explanatory drawing, showing the write operation of memory cell MC of this embodiment. The MTJ element of memory cell MC of this embodiment is connected to the bit line BL1. Cell transistor CT is an N-type Field-Effect Transistor (FET) and is connected to the bit line BL 2. The MTJ element that utilizes the tunneling magnetoresistive (TMR) effect has a layered structure with two ferromagnetic layers F and P and nonmagnetic layer (tunnel insulating film) B, which is disposed between them, and stores data using changes in magnetic resistance due to the spin polarization tunnel effect. The MTJ element can take a low-resistive state and a high-resistive state, depending on the direction of magnetization of two ferromagnetic layers F and P. For example, when the low-resistive state is defined as datum “1,” and the high-resistive state is defined as datum “0,” it is possible to record 1 bit of data in the MTJ element. However, the low-resistive state can be defined as datum “0,” and the high resistive state can be defined as datum “1.”

For example, the MTJ element is composed by sequentially layering the recording layer (free layer) F, the tunnel barrier layer B, and the fixed layer (pin layer) P. The pin layer P and the free layer F are composed of ferromagnetic materials, and the tunnel barrier B is composed of an insulating film (for example Al₂O₃, and MgO). The pin layer P is a layer in which the direction of magnetization is fixed. The free layer F has a variable magnetization direction and stores data according to the direction of magnetization.

By applying a current in the direction of arrow A1 during the write operation, the magnetization directions of the pin layer P and the free layer F become parallel (P state), which is a low-resistive state (datum “1”). By applying a current in the direction of arrow A2 during the write operation, the magnetization direction of the free layer F is put in an antiparallel state (AP state) against that of the pin layer P, which is a high-resistive state (datum “0”). In this way, the MTJ element can write different data depending on the direction of the current applied. Here, in FIG. 2, the cell transistor CT is an N-type FET, but the cell transistor can also be a P-type FET.

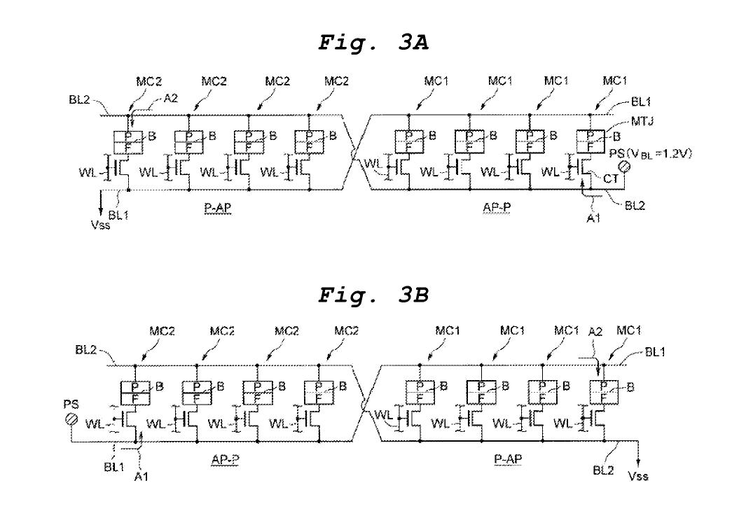

FIGS. 3A and 3B are equivalent circuit schematics, showing part of the MRAM during the write operation. The MRAM of this embodiment has multiple memory cells MC1 and MC2, which are connected in parallel between the first bit line BL1 and the second bit line BL2. Both of a memory cell MC1 and a memory cell MC2 have an MTJ element and a cell transistor CT, which are connected in series between the first bit line BL1 and the second bit line BL2.

In this embodiment, the cell transistor CT is an N-type FET. The gate of the cell transistor CT is connected to word line WL.

Each MTJ element of the multiple memory cells MC1 (the first memory cell) is connected to the first bit line BL1, and each cell transistor CT of the multiple memory cells MC1 is connected to the second bit line BL2.

Each MTJ element of the multiple memory cells MC2 (the second memory cell) is connected to the second bit line BL2, and each cell transistor CT of the multiple memory cells MC2 is connected to the first bit line BL1.

In memory cells MC1, the pin layer P, the barrier layer B, and the free layer F of the MTJ element are arranged in the order of the pin layer P, the barrier layer B, and the free layer F from the first bit line BL1 toward the cell transistor CT.

In memory cells MC2, the pin layer P, the barrier layer B, and the free layer F of the MTJ element are arranged in the order of the pin layer P, the barrier layer B, and the free layer F from the second bit line BL2 toward cell transistor CT. Namely, the MTJ elements of the memory cells MC1 and MC2 are formed with a so-called “bottom-free” structure.

Furthermore, the first and the second bit lines BL1 and BL2 cross each other while maintaining isolation from one another between the memory cells MC1 and MC2. Consequently, the first bit line BL1 is connected to the MTJ element of the memory cell MC1 and to the cell transistor CT of the memory cell MC2. The second bit line BL2 is connected to the cell transistor CT of the memory cell MC1 and to the MTJ element of the memory cell MC2.

In the write operation shown in FIG. 3A, datum “1” is written into the memory cell MC1, and datum “0” is written into the memory cell MC2. In the write operation shown in FIG. 3B, when a write voltage is applied to node PS in the lower left of the figure, datum “0” is written into the memory cell MC1 and datum “1” is written into the memory cell MC2.

The write operation will be explained using FIG. 3A and FIG. 3B. According to FIG. 3A, power source PS is connected to the second bit line BL2, and the power source PS is closer to memory cell MC1 than to the memory cell MC2. The low-voltage source Vss (for example, ground potential) is connected to the first bit line BL1, and the low-voltage source Vss is closer to the memory cell MC2 than to the memory cell MC1. In this case, the write current flows from the second bit line BL2 to the first bit line BL1. If any one of the memory cells MC1 is selected by applying a voltage to their word line WL, the write current flows from the cell transistor CT of the memory cell MC1 to the MTJ element. In other words, the write current flows in the direction of arrow A1. The current in the direction of arrow A1 is, as explained using FIG. 2, the current that changes the MTJ element from the AP state to the P state and that writes datum “1.” In the following, the write current for datum “1” is called current I_{AP-P}.

On the other hand, if any one of memory cells MC2 is selected, the write current flows from the MTJ element of the memory cell MC2 to the cell transistor CT. In other words, the write current flows in the direction of arrow A2. The current in the direction of arrow A2 is, as explained using FIG. 2, the current that changes the MTJ element from the P state to the AP state and that write datum “0”. In the following, the write current for datum “0” is called current I_{P-AP}.

Here, in FIG. 3A, the memory cells MC1 are positioned closer to power course PS than are the memory cells MC2, but these memory cells MC1 are positioned farther from low-voltage source Vss than are the memory cells MC2. Therefore, the length along the first bit line BL1 from the source of the cell transistor CT of the memory cell MC1 to the low-voltage source Vss is longer than the length along the first bit line BL1 from the source of the cell transistor CT of the memory cell MC2 to the low voltage source Vss. Furthermore, between the cell transistor CT of the memory cell MC1 and the first bit line BL1, an MTJ element is disposed. Therefore, the parasitic resistance from the source of the cell transistor CT of the memory cell MC1 to the low-voltage source Vss is the sum of the wiring resistance of the first bit line BL1 and the resistance of the MTJ element.

On the other hand, the memory cells MC2 are closer to the low-voltage source Vss than are the memory cells MC1. Therefore, the length along the first bit line BL1 from the source of the cell transistor CT of the memory cell MC2 to the low-voltage source Vss is shorter than that of the memory cell MC1. Additionally, the MTJ element is not disposed between the cell transistor CT of the memory cell MC2 and the first bit line BL1.

Therefore, the parasitic resistance from the source of cell transistor CT to the memory cell MC1 to the low-voltage source Vss is greater than the parasitic resistance from the source of the cell transistor CT of the memory cell MC2 and the low-voltage source Vss.

When the parasitic resistance from the source to the low-voltage source Vss is large, the source voltage increases (floats) to a value greater than the value of the voltage of the low-voltage source Vss. In this case, the voltage between the gate and the source of the cell transistor CT decreases, and the current driving capacity of the cell transistor CT declines. Therefore, write current I_{AP-P} that flows in the memory cell MC1 becomes smaller than write current I_{P-AP} that flows in the memory cell MC2.

Here, normally, when the MTJ element is transferred from the P state to the AP state (during “0” write operation), it is necessary to apply a relatively large current to the MTJ element. On the other hand, when MTJ element is transferred from the AP state to the P state (during “1” write operation), only a relatively small current needs to be applied to the MTJ element. In other words, the write current needed to transfer from the AP state to the P state (in the following, it is called transition threshold current It_{AP-P}) is smaller than the write current needed to transfer the P state to the AP state (in the following, it is called transition threshold current It_{P-AP}) (i.e., It_{AP-P}<It_{P-AP}).

Datum “1” can be written into the MTJ element if the write current I_{AP-P} exceeds the transition threshold current It_{AP-P} Datum “0” can be written into the MTJ element if the write current I_{P-AP} exceeds the transition threshold current It_{P-AP}.

As previously discussed, the actual write current I_{AP-P} that flows in memory cell MC1 becomes smaller as the current driving capability of the cell transistor CT declines. However, the transition threshold current It_{AP-P} is small in the first place, so even if the actual write current I_{AP-P}=is small, as long as it exceeds transition threshold current It_{AP-P}, there will be no problem.

On the other hand, the transition threshold current It_{P-AP} in the memory cell MC2 is large. However, the current driving capability of the cell transistor CT of memory cell MC2 is greater than that of the memory cell MC1; as a result, the actual write current I_{P-AP} is also large. Therefore, even if the transition threshold current It_{P-AP} is large, as long as the actual write current I_{P-AP} exceeds the transition threshold current It_{P-AP}, there will be no problem.

According to FIG. 3B, power source PS is connected to the first bit line BL1, which is close to memory cell MC2, and the low-voltage source Vss is connected to the second bit line BL2, which is close to the memory cell MC1. In this case, the write current flows from the first bit line BL1 to the second bit line BL2. If any of the memory cells MC1 is selected in this condition, the write current flows in the direction of arrow A2 in the memory cell MC1. On the other hand, if any of the memory cells MC2 is selected, the write current flows in the direction of arrow A1 in the memory cell MC2. Therefore, in FIG. 3B, datum “0” is written into the memory cell MC1, and datum “1” is written into the memory cell MC2.

Here, a memory cell MC2 is farther from low-voltage source Vss than a memory cell MC1 is. Therefore, the length along the second bit line BL2 from the source of the cell transistor CT of a memory cell MC2 to the low-voltage source Vss is longer than the length along the second bit line BL2 from the source of the cell transistor CT of a memory cell MC1 to the low-voltage source Vss. Furthermore, the MTJ element is disposed between the cell transistor CT of the memory cell MC2 and the second bit line BL2. On the other hand, the memory cells MC1 are closer to the low-voltage source Vss than are the memory cells MC2. Therefore, the length along the second bit line BL2 from the source of the cell transistor CT of the memory cells MC1 to the low-voltage source Vss are shorter than that of the memory cells MC2. Furthermore, no MTJ element exists between the cell transistor CT of the memory cell MC1 and the second bit line BL2. Therefore, the parasitic resistance from the source of the cell transistor CT of the memory cell MC2 to the low-voltage source Vss is greater than that of the first bit line BL1.

In this way, when the parasitic resistance from the source to the low-voltage source Vss is large, as previously discussed, the current driving capability of cell transistor CT deteriorates. Therefore, write current I_{AP-P} that flows in the memory cell MC2 is smaller than write current I_{P-AP} that flows in the memory cell MC1.

However, as previously discussed, the transition threshold current It_{AP-P} is smaller than the transition threshold current It_{P-AP} (It_{AP-P}<It_{P-AP}). In other words, the transition threshold current It_{P-AP} is small in the first place, so even if the actual write current I_{AP-P} is small, as long as it exceeds the transition threshold current It_{P-AP}, datum “1” is written without any problem.

On the other hand, the transition threshold current It_{P-AP} at the memory cell MC1 is large. However, the current driving capability of the cell transistor CT of the memory cell MC2 is greater than that of the memory cell MC1, so the actual write current I_{P-AP} is large. Therefore, even if the transition threshold current It_{P-AP} is large, as long as the actual write current I_{P-AP} exceeds the transition threshold current It_{P-AP}, datum “0” is written without any problem.

As a result, in this embodiment, by letting the first and the second bit lines BL1 and BL2 switch between a memory cell MC1 and a memory cell MC2, the amount of the actual write currents I_{AP-P} and I_{P-AP} can be conformed to the amount of transition threshold currents It_{AP-P} and It_{P-AP}. In other words, when a memory cell MC1 or MC2 is close to power source PS, and the current driving capability of the cell transistor CT is small, the write current is applied from a free layer F to a pin layer P (AP to P) so that the transition threshold current decreases. Conversely, when a memory cell MC1 or MC2 is far from power source PS, and the current driving capability of the cell transistor CT is large, accordingly, the write current is applied in a direction toward a large transition threshold current, namely in the direction from a pin layer P to a free layer F (P to AP). Consequently, this embodiment compensates for the difference in the voltage decrease, which depends on the positioning of memory cells MC1 and MC2, and can suppress the inferior write operation from occurring.

Here, memory cells MC1 and MC2 are connected to the same pair of bit lines BL1 and BL2. However, since bit lines BL1 and BL2 switch with each other, when power source PS is connected to either the bit line BL1 or the bit line BL2, data of reverse logic are stored reciprocally in the memory cells MC1 and MC2. This problem will be solved by changing the position of the power source PS or changing the address, corresponding to the logic of the data to be written.

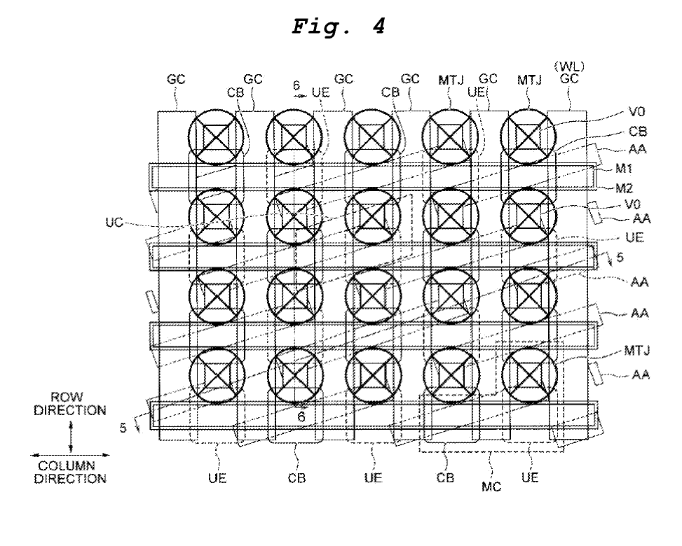

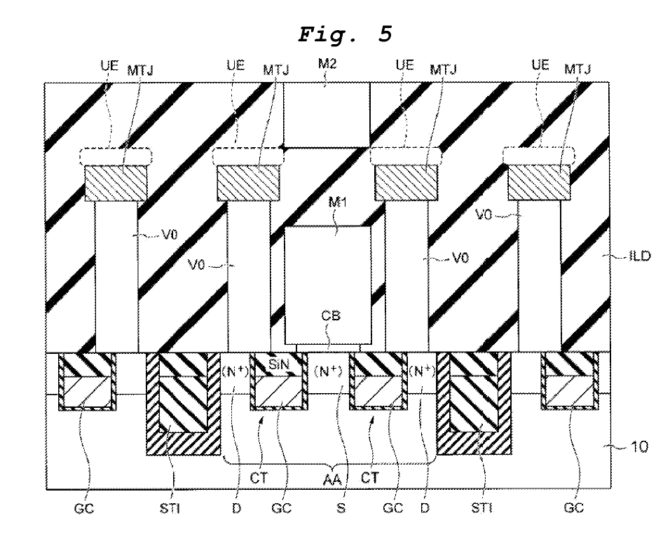

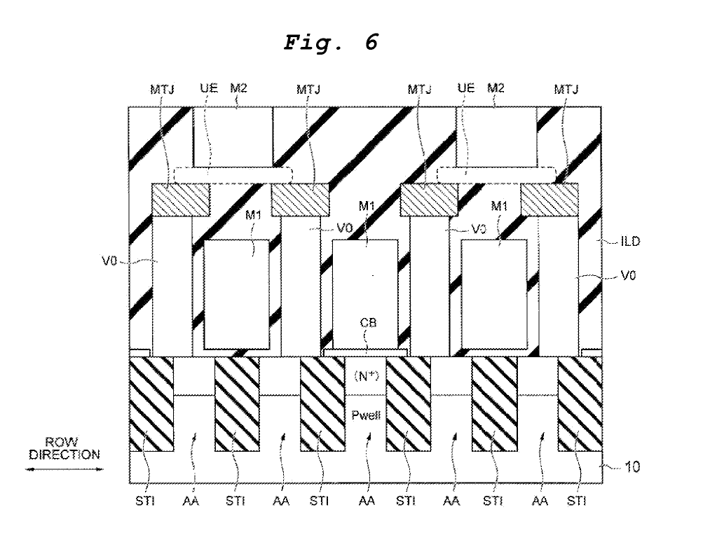

FIG. 4 is a plane layout chart of the MRAM of the first embodiment. FIG. 5 is a cross section of FIG. 4 along the 5-5 line (active area AA). FIG. 6 is a cross section of FIG. 4 along the 6-6 line (in the row direction).

As shown in FIG. 4, the direction in which gate electrode GC extends is defined as the row direction (the first direction), and the direction that crosses almost orthogonally to the row direction is defined as the column direction (the second direction). The bit line BL extends in the column direction.

As shown in FIGS. 5 and 6, the MRAM of this embodiment is formed on semiconductor substrate 10. On the semiconductor substrate 10, active area AA and element isolation area Shallow Trench Isolation (STI) are alternately formed. In the active area AA, cell transistors CT are formed. As shown in FIG. 5, the cell transistor CT includes gate electrode GC, which is embedded in the semiconductor substrate 10, and an N+ type source diffusion layer S and a drain diffusion layer D are located to either side of the gate electrode GC. Here, the gate electrode GC is insulated and isolated from the semiconductor substrate 10 and wirings M1 and M2.

In an active area AA, two cell transistors CT are formed. The two cell transistors CT share a source or a drain with each other. Here, the two cell transistors CT share the source s.

The source S shared by the cell transistors CT is connected to the first wiring M1, which is formed by the first metal wiring layer through contact plug CB. The first wiring M1 is connected to either bit line BL1 or BL2.

Drain D of the cell transistor CT is electrically connected through via contact V0 to the bottom end of MTJ element (for example, the free layer).

The upper end of the MTJ element (for example, the pin layer) is connected to upper electrode UE. As shown in FIG. 6, in the row direction, the upper ends of the two adjacent MTJ elements are connected to the shared upper electrode UE, and the upper electrode UE is connected to the wiring M2, which is formed by the second metal wiring layer. The second wiring M2 is connected to either the bit line BL1 or the bit line BL2.

Inter-Layer Dielectric (ILD) is an inter-layer insulation film that insulates the wirings from one another.

Where a gate electrode GC and an active area AA intersect as seen on FIG. 4, the cell transistors CT shown in FIG. 5 are located. Two cell transistors CT are disposed in each active area AA. The MTJ element is, as shown in FIG. 5, disposed on via contact V0 between contact plug CB and the upper electrode UE. Two MTJ elements are formed in such a way as they overlap at both ends of the active area AA, and each is connected to the source S through its corresponding cell transistor CT. One MTJ element and one cell transistor CT constitute a memory cell MC. In other words, the active area AA includes two cell transistors CT (every memory cell MC) along the length direction of the active area AA, and thus two memory cells MC are disposed in each active area AA.

As shown in FIG. 4, the active areas AA do not intersect the row direction perpendicularly, nor are they parallel to the column direction, and one memory cell MC is formed in a roughly L shape, where the cell transistor CT is shifted to the side of the overlying corresponding MTJ element along the length of the active area. Here, the size of unit cell UC of MRAM in this embodiment is 6F² (3F×2F), which is very small. Therefore, the MRAM of this embodiment can be used as a substitute for the DRAM. The MRAM is a nonvolatile memory, so it can also be used for the EEPROM. Here, F (Feature Size) is the smallest fabrication size using the lithography and etching techniques. An example of achievable feature sizes is set forth below.

During the write or the read operation, in order to select a certain memory cell MC, a gate electrode GC (word line WL) corresponding to this memory cell MC is set to drive, i.e., powered. As a result, the multiple cell transistors CT connected to its word line WL and arranged in the row direction are placed in the conductive state. By applying the voltage difference to the pair of bit lines BL1 and BL2 of a certain column, the memory cell MC that corresponds to the intersection of the selected word line WL and the selected pair of the bit lines BL1 and BL2 is selected, and a current can be applied through cell transistor CT to the MTJ element of the selected memory cell MC.

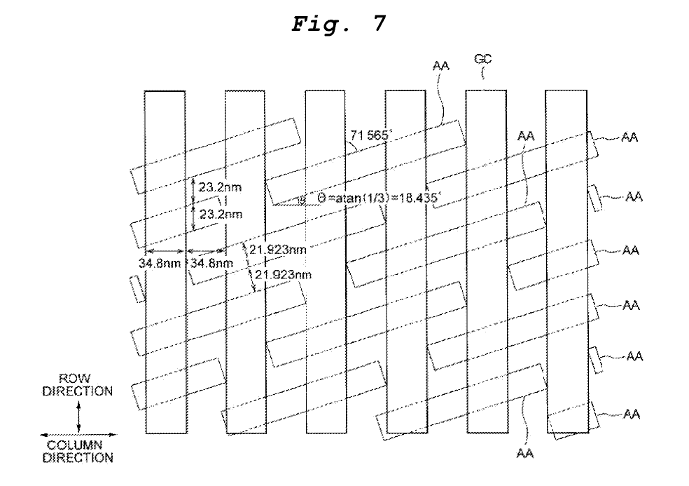

FIG. 7 is a plane drawing, showing active areas AA and gate electrodes GC (word lines WL). The active areas AA of this embodiment extends at the angle of (90−atan(⅓)) or 18.435 degrees with respect to the gate electrodes GC. In other words, the active areas AA are slanted at an angle of approximately 71.565 degrees with respect to the row direction. Or, the active areas AA are slanted at an angle of approximately 18.435 degrees against the column direction.

Also, in this embodiment, the width of the gate electrodes GC (word lines WL) in the column direction or the interval between the gate electrodes GC (word lines WL) adjacent to each other is 3/2 times or 2/3 times the width of an active area AA or the width of the interval between the active areas AA adjacent to each other.

For example, the width of a gate electrode GC in the column direction or the width of the interval between the two gate electrodes GC adjacent to each other is approximately 34.8 nm. The width of an active area AA or the gap between adjacent active areas is approximately 21.923 nm. Active area AA is slanted at the angle of atan (⅓) degrees (approximately 18.435 degrees) against the column direction. Therefore, the width of the active area AA in the row direction, and the gap between the adjacent active areas AA is approximately 23.2 nm as measured parallel to the row direction. The width of the gate electrode GC in the column direction or the interval between the gate electrodes GC adjacent to each other is 3/2 times the width of the active area AA in the row direction or the interval between the active areas AA adjacent to each other.

The pitch of the bit line BL is also 1.5 times longer than the pitch of the active area AA, so the ratio of the pitch of the bit line BL (column) to the pitch of the word line WL (row) is 1:1. On the other hand, the ratio of the Line width and Spacing between active areas AA to the Line width and Spacing between gate electrodes GC (word line WL) is 2:3.

In this way, by inclining active areas AA at the angle of (90−atan(⅓)) degrees from the row direction, and by setting the pitch ratio of active areas AA to gate electrodes GC (word line WL) to be 2:3, as shown in FIG. 7, the MTJ elements can be arranged at the same interval (the same pitch) in the column direction and the row direction, as shown in FIG. 4. In this concrete example, the interval between the MTJ elements adjacent in the column direction or the row direction is approximately 69.6 nm.

In this way, by arranging the MTJ elements at the same interval in the column direction and the row direction on the plane layout, it is possible to suppress the dispersion in shape and size (dispersion of the process) of the MTJ element during the MRAM production process. Also, as the MTJ elements are arranged at the same interval in the column direction and the row direction, even if the interval between the adjacent MTJ elements becomes narrow, the MTJ elements can be easily processed using currently available lithography and the etching techniques during the MRAM production process.

Furthermore, the MTJ elements are disposed in correspondence with all the intersections of multiple rows and multiple columns of the MTJ elements. Therefore, the MTJ element can be also formed during the etching process of the MTJ element by using multiple sidewalls formed in the row and column directions as a mask. Consequently, the MTJ element can be formed without using additional lithography techniques. As a result, the MRAM production process will be expedited. Also, the sidewalls can be made narrower than the smallest production size F. Therefore, by using this sidewall mask production technique, the size of MTJ element can be further reduced.

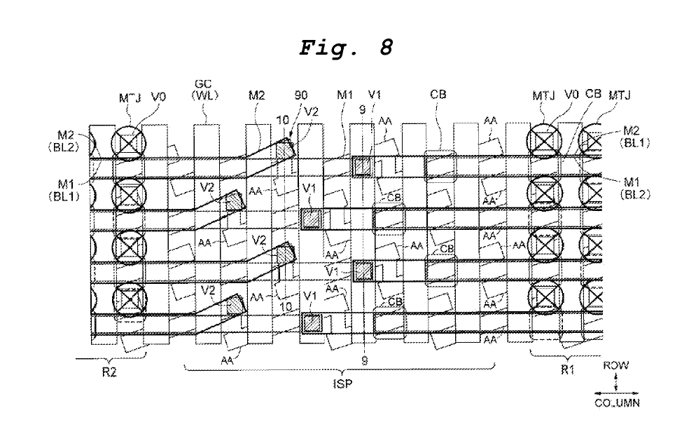

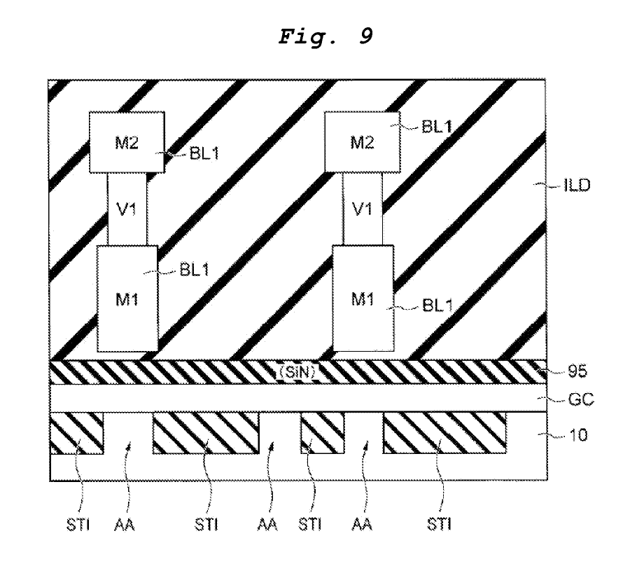

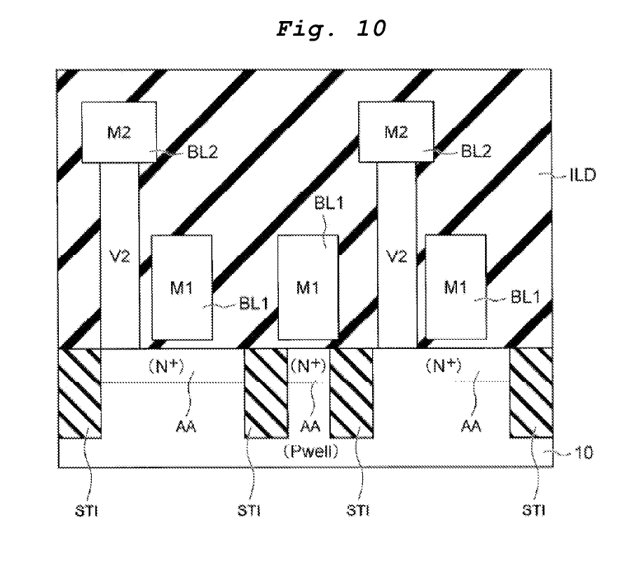

FIG. 8 is a plane drawing, showing the intersection part ISP of the first bit line BL1 and the second bit line BL2. FIG. 9 is a cross section of FIG. 8 along 9-9 line. FIG. 10 is a cross section of FIG. 8 along 10-10 line.

As shown in FIG. 8, the first bit lines BL1 and the second bit lines BL2 are formed with the first wiring M1 or the second wiring M2. The second wiring is formed above the first wiring. In area R2, where the first bit line BL1 is formed with the first wiring M1, the second bet line BL2 is formed with the second wiring M2. In area R1, where the first bit line BL1 is formed with the second wiring M2, the second bit line BL2 is formed with the first wiring M1.

The area of switching locations of the bit lines (ISP) is formed to switch the first bit line BL1 from the second wiring M2 to the first wiring M1 and to switch the second bit line BL2 from the first wiring M1 to the second wiring M2. Therefore, no MTJ element is disposed at intersection ISP.

The second wiring M2 extending within region R1, and which in the region R1 forms the first bit line BL1, extends from the area R1 to intersection part ISP, and is connected to the first wiring M1 of area R2 through a three dimensional routing in the ISP area, through via contact V1. Consequently, as shown in FIGS. 3A and 3B, the connection of the first bit line BL1 is switched from the MTJ element side of the memory cell MC1 to the cell transistor CT side of the memory cell MC2.

The first wiring M1 which forms the second bit line BL2 in region R1, extends from the area R1 to the intersection part ISP, and is there connected to an active area AA through contact plug CB. The active area AA of the intersection part ISP is different from the active areas AA of the areas R1 and R2, as the active areas aligned along a column direction are connected at their adjacent ends. Also, the length of the active area AA is, as explained using FIG. 7, slanted or angled with respect to the column direction, and part 90 exists and protrudes from, or is offset from the location of, the first wiring layer M1 and second wiring layer M2 in the plane layout shown in FIG. 8. At this protruded area 90, the active area AA is connected to the second wiring M2, which extends from intersection part ISP to area R2, through via contact V2. In other words, at the intersection part ISP, the first wiring M1 is connected to the second wiring M2 through the contact plug CB, the active area AA, and the via contact V2. As a result, as shown in FIGS. 3A and 3B, the connection of the second bit line BL2 is switched from the cell transistor CT side of the memory cell MC1 to the MTJ element side of the memory cell MC2.

According to this embodiment, at the intersection part ISP of the memory cell MC1 and the memory cell MC2, wiring M1 (or M2) of the first bit line BL1 and the wiring M2 (or M1) of the second bit line BL2 are replaced with each other.

At the intersection part ISP, the first wiring M1 that extends from the area R1 to the intersection part ISP and the first wiring M1 that extends from the intersection part ISP to the area R2 become discontinuous, as the M2 wiring in R1 connects with the M1 wiring in R2, and vice versa. The second wiring M2 that extends from the area R1 to the intersection part ISP and the second wiring M2 that extends from the intersection part ISP to the area R2 are likewise discontinuous at the ISP region. Therefore, the first bit line BL1 and the second bit line BL2 may be crossed intersect while being electrically insulated or isolated from each other.

FIG. 9 shows a cross section where the first bit line BL1 is switched from the first wiring M1 to the second wiring M2. Specifically, the gate electrode GC is formed on the active area AA of the semiconductor substrate 10 and the element isolation area STI. On the gate electrode GC, Sin cap 95 is formed. On the Sin cap 95, the first wiring M1, the via contact V1, and the second wiring M2 are formed. The interlayer insulation film ILD is embedded on the periphery of the first wiring M1, the via contact V1, and the second wiring M2. In this way, the first bit line BL1 is switched by the via contact V1 between the first wiring M1 and the second wiring M2.

FIG. 10 shows a cross section where the second bit line BL2 is connected to the active area AA. Here, at intersection part ISP, the adjacent active areas AA are connected by the N+diffusion layer. The active area AA is connected to the second wiring M2 (the second bit line BL2) through the via contact V2. The via contact V2 and the second wiring M2 are formed in protruded area 90 of FIG. 8. Also, on the active area AA, the first wiring M1 (the first bit line BL1) is formed, with the insulating film placed in between them. On the periphery of the first wiring M1, the via contact V2, and the second wiring M2, interlayer insulating film ILD is embedded. In this way, the second bit line BL2 is connected to the active area AA by the via contact V2.

Here, the structure of the part in which the first wiring M1 is connected to the active area AA through the contact plug CB can be easily understood by the first wiring M1, contact plug CB, and N+ diffusion layer, shown in FIG. 6. Therefore, the figure is omitted here.

In this way, according to the MRAM of the first embodiment, at the equivalent circuit, the first bit line BL and the second bit line BL2 can cross between the memory cell MC1 and the memory cell MC2, while being electrically insulated from each other. Consequently, the amount of the actual write currents I_{AP-P} and I_{P-AP} can be conformed to the amount of transition threshold currents It_{AP-P} and It_{P-AP}. As a result, this embodiment can compensate for the dispersion in voltage decrease across a long chain of memory cell transistors along a bit line, and thereby suppress inferior write operations.

### Second Embodiment

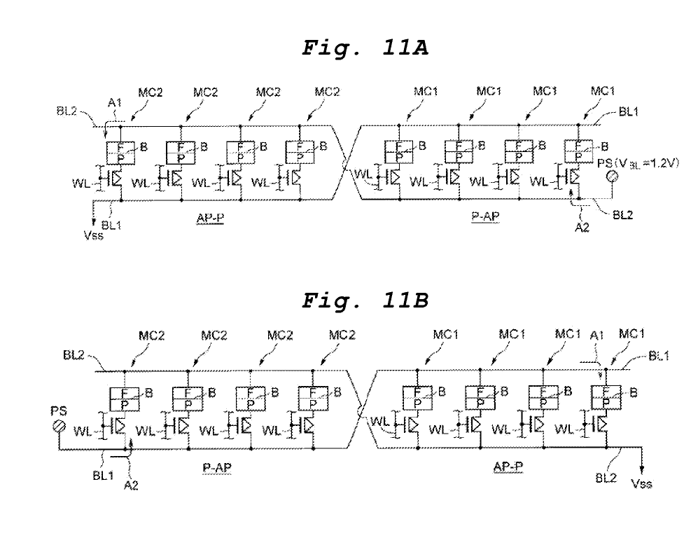

FIGS. 11A and 11B are equivalent circuit schematics, showing part of the MRAM during the write operation according to the second embodiment. In the MRAM of the second embodiment, the cell transistor CT is a P-type FET.

In the memory cell MC1, the free layer F, the barrier layer B, and the pin layer P of the MTJ element are arranged in the order of the free layer F, the barrier layer B, and the pin layer P from the first bit line BL1 toward the cell transistor CT.

In the memory cell MC2, the free layer F, the barrier layer B, and the pin layer P of the MTJ element are arranged in the order of the free layer F, the barrier layer B, and the pin layer P from the second bit line BL2 toward the cell transistor CT. In other words, in the second embodiment, the MTJ elements of the memory cells MC1 and MC2 are formed with a so-called “top-free” structure. The structure of the MRAM and others of the second embodiment can be the same as the structure corresponding to the MRAM of the first embodiment.

In the write operation shown in FIG. 11A, datum “0” is written into the memory cell MC1, and datum “1” is written into the memory cell MC2. In the write operation shown in FIG. 11B, datum “1” is written into the memory cell MC1, and datum “0” is written into the memory cell MC2.

The write operation will be explained using FIGS. 11A and 11B. As seen in FIG. 11A, the power source PS is connected to the second bit line BL2 and is closer to the memory cell MC1 than to the memory cell MC2. The low-voltage source Vss is connected to the first bit line BL1 and is closer to the memory cell MC2 than to the memory cell MC1. In this case, the write current flows from the second bit line BL2 to the first bit line BL1. Under this condition, if any of the memory cells MC1 are selected by applying a voltage on line WL, the write current flows in the direction of A2, from the cell transistor CT of memory cell MC1 to the MTJ element. Namely, current I_{P-AP} flows to write datum “0.”

On the other hand, if any of the memory cells MC2 are selected, the write current flows in the direction of A1, from the MTJ element of the memory cell MC2 to the cell transistor CT. Namely, current I_{AP-P} flows to write datum “1.”

Here, the memory cell MC1 is positioned closer to power source PS than is the memory cell MC2. Conversely, the memory cell MC1 is positioned farther from the low-voltage source Vss than is the memory cell MC2. Furthermore, an MTJ element is disposed between the cell transistor CT of the memory cell MC1 and the first bit line BL1.

On the other hand, the memory cell MC2 is closer to the low-voltage source Vss than is the memory cell MC1. Furthermore, no MTJ element is disposed between the cell transistor CT of the memory cell MC2 and the first bit line BL1.

Therefore, the parasitic resistance from the source of the cell transistor CT of the memory cell MC1 to the low-voltage source Vss is greater than the parasitic resistance from the source of cell transistor CT of the memory cell MC2 to the low-voltage source Vss. When the parasitic resistance from the source to the low-voltage source Vss is large, the source voltage increases (floats) more than the voltage of the low-voltage source Vss.

However, in the second embodiment, the cell transistor CT is a P-type FET. Therefore, if the source voltage increases, the current driving capability of the cell transistor CT increases. In other words, the write current I_{P-AP} that flows in the memory cell MC1 becomes larger than the write current I_{AP-P} that flows in the memory cell MC2.

As previously discussed, the transition threshold current It_{P-AP} is greater than the transition threshold current It_{AP-P} (It_{AP-P}<It_{P-AP}), but the actual write current at the memory cell MC1 is correspondingly larger. As a result, even if the transition threshold current It_{P-AP} is large, as long as the actual write current I_{P-AP} exceeds the transition threshold current It_{P-AP}, datum “0” can be written.

On the other hand, the memory cell MC2 is closer to the low-voltage source Vss than the memory cell MC1 is. Therefore, the current driving capability of the cell transistor CT of the memory cell MC2 is relatively small. Additionally, the actual write current I_{AP-P} that flows in the memory cell MC2 decreases as the current driving capability of the cell transistor CT declines. However, the transition threshold current is small in the first place, so even if the actual current I_{AP-P} is small, as long as it exceeds the transition threshold current It_{AP-P}, datum “1” can be written.

As seen in FIG. 11B, the power source PS is connected to the first bit line BL1 and is closer to the memory cells MC2 than to the memory cells MC1. The low-voltage source Vss is connected to the second bit line BL2 and is closer to the memory cells MC1 than to the memory cells MC2. In this case, the write current flows from the first bit line BL1 to the second bit line BL2. Under this condition, if any of the memory cells MC1 is selected, the write current I_{AP-P} flows in the direction of arrow A1 in the memory cell MC1.

On the other hand, if any of the memory cells MC2 is selected, the write current I_{P-AP}, flows in the direction of arrow A2 in the memory cell MC2. Therefore, in FIG. 11B, datum “1” is written into the memory cell MC1, and datum “0” is written into the memory cell MC2.

Here, the memory cells MC2 are farther from the low-voltage source Vss than are the memory cells MC1. Furthermore, an MTJ element is disposed between the cell transistor CT of the memory cells MC2 and the second bit line BL2. On the other hand, the memory cells MC1 are closer to the low-voltage source Vss than are the memory cells MC2. Additionally, no MTJ element is disposed between the cell transistor CT of the memory cells MC1 and the second bit line BL2. Therefore, the parasitic resistance from the source of the cell transistor CT of the memory cells MC2 to the low-voltage source Vss is greater than the parasitic resistance from the source of cell transistor CT of the memory cells MC1 to the low-voltage source Vss. When the parasitic resistance from the source to the low-voltage source Vss is large, the source voltage increase (floats) more than the voltage of the low-voltage source Vss.

However, in the second embodiment, the cell transistor CT is a P-type FET. Therefore, when the source voltage increases, the current driving capability of the cell transistor CT also increases. In other words, the write current I_{P-AP} that flows in the memory cell MC2 is larger than the write current I_{AP-P} that flows in the memory cell MC1.

As previously discussed, the transition threshold current It_{P-AP} is larger than the transition threshold current It_{AP-P} (It_{AP-P}<It_{P-AP}). However, the actual write current at the memory cell MC2 I_{P-AP} also becomes correspondingly large. As a result, even if the transition threshold current It_{P-AP} is large, as long as the actual write current I_{P-AP} exceeds the transition threshold current It_{P-AP}, datum “0” can be written.

On the other hand, the source voltage of the memory cells MC1 is close to the low-voltage source Vss. Therefore, the current driving capability of the cell transistor CT of the memory cells MC1 is relatively small. Therefore, the actual write current at the memory cell MC1 I_{AP-P} decreases as the current driving capability of the cell transistor CT declines. However, the transition threshold voltage It_{AP-P} is small in the first place, so even if the actual write current I_{AP-P} is small, as long as it exceeds the transition threshold current It_{AP-P}, datum “1” can be written.

In this way, according to the second embodiment, by letting the first line BL1 and the second bit line BL2 cross between the first memory cell MC1 and the second memory cell MC2 through the IPS region, the amount of the actual write currents I_{AP-P} and I_{P-AP} can be conformed to the amount of the transition threshold currents It_{AP-P} and It_{P-AP}. Therefore, the second embodiment also can achieve the same effect as the first embodiment.

Here, the plane layouts and cross sections of the MRAM of the second embodiment can be the same as FIG. 4 through FIG. 10 of the first embodiment. However, the conductive type of the diffusion layer of the second embodiment is a conductive type reversed from those in the first embodiment.

While certain embodiments have been described, these embodiments have been presented by way of example only, and they are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a first bit line;
a second bit line; and
at least two memory cells that are connected in parallel between the first and the second bit lines, each of the memory cells including a memory element and a transistor that are connected in series between the first bit line and the second bit line,
wherein
in the first memory cell, the memory element is connected to the first bit line, and the transistor is connected to the second bit line, and
in the second memory cell, the memory element is connected to the second bit line, and the transistor is connected to the first bit line.

2. The semiconductor memory device according to claim 1, wherein
the first and the second bit lines cross in a location intermediate of the first and the second memory cells.

3. The semiconductor memory device according to claim 1, wherein
when datum is written by letting a current flow from the first bit line to the second bit line,
if the datum is written into the first memory cell, the write current flows from the memory element to the transistor at the first memory cell; and
if the datum is written into the second memory cell, the write current flows from the transistor to the memory element at the second memory cell.

4. The semiconductor memory device according to claim 2, wherein
when datum is written by letting a current flow from the first bit line to the second bit line,
if the datum is written into the first memory cell, the write current flows from the memory element to the transistor at the first memory cell; and
if the datum is written into the second memory cell, the write current flows from the transistor to the memory element at the second memory cell.

5. The semiconductor memory device according to claim 1, wherein
the transistor of the first and the second memory cells is an N-type transistor.

6. The semiconductor memory device according to claim 5, wherein
each memory element of the first and the second memory cells includes a magnetic tunnel junction device that includes a free layer, a barrier layer, and a pin layer,
in the first memory cell, the free layer, the barrier layer, and the pin layer are arranged from the first bit line toward the transistor in the order of the pin layer, the barrier layer, and the free layer, and
in the second memory cell, the free layer, the barrier layer and, the pin layer are arranged from the second bit line toward the transistor in the order of the pin layer, the barrier layer, and the free layer.

7. The semiconductor memory device according to claim 6, wherein
the second bit line is connected to a power source, and
the first cell is disposed closer to the power source than is the second cell.

8. The semiconductor memory device according to claim 1, wherein
each memory element of the first and the second memory cells is a magnetic tunnel junction device that includes a free layer, barrier layer, and pin layer,
in the first memory cell, the free layer, the barrier layer, and the pin layer are arranged from the first bit line toward the transistor in the order of the free layer, the barrier layer, and the pin layer, and
in the second memory cell, the free layer, the pin layer, and the barrier layer are arranged from the second bit line toward the transistor in the order of the free layer, the barrier layer, and the pin layer, and
the transistor of the first and the second memory cells is a P-type transistor.

9. A semiconductor memory device, comprising:
a first region having memory cells connected between first and second bit lines, wherein each memory cell includes at least a cell transistor and a memory unit, and the cell transistor sources are connected to the first bit line;
a second region having memory cells connected between first and second bit lines wherein each memory cell includes at least a cell transistor and a memory unit, and the cell transistor sources are connected to the second bit line; and
an intermediate region between the first and second regions, wherein the first bit line of the first region is electrically connected to the second bit line of the second region.

10. The semiconductor memory device of claim 9, wherein a voltage source is connected to the first bit line in the first region and a ground potential is applied to the first bit line in the second region.

11. The semiconductor memory device of claim 9, wherein the first, second and intermediate regions are located on the surface of a substrate, and the first bit line is closer to the surface of the substrate than is the second bit line, and an interconnect extends from the position of the first bit line to the second bit line in the intermediate region.

12. The semiconductor memory device of claim 11, wherein the interconnect in the intermediate region further includes an offset portion arranged substantially in the plane of one of the bit lines and is offset in a direction generally perpendicular to the length direction of the bit line.

13. The semiconductor memory of claim 12, wherein the memory unit in a memory cell is an MTJ memory unit.

14. A method of providing interconnection to a plurality of memory cells, comprising;
providing a first plurality of memory cells connected between first and second bit lines wherein each memory cell includes at least a cell transistor and a memory unit, and the cell transistor sources are connected to the first bit line;
providing a second plurality of memory cells connected between first and second bit lines wherein each memory cell includes at least a cell transistor and a memory unit, and the cell transistor sources are connected to the second bit line; and
connecting the first bit line of the first region to the second bit line of the second region.

15. The method of claim 14, further comprising the step of forming the memory unit as an MTJ memory unit.

16. The method of claim 14, further including the steps of:
providing a plurality of wordlines extending generally parallel to one another;
providing at least two bit lines extending generally parallel to each other and perpendicular to the word lines; and
providing at least one active area positioned at an angle which is non-perpendicular to the word lines and bit lines.

17. The method of claim 16, where a single active area extends across the region of two adjacent bit lines.

18. The method of claim 17, wherein a transistor is formed at the opposed portions of a single active area.

19. The method of claim 18, wherein an MTC unit is located in an overlying conductive position with respect to the transistors formed at the opposed portions of a single active area.

20. The method of claim 19, wherein the active area is a portion of an underlying semiconductor substrate.
